(19) United States
(12) Patent Application Publication
(10) Pub. No.: US 2026/0026081 A1
(43) Pub. Date: Jan. 22, 2026

(54) ISOLATION STRUCTURE WITH HARD MASK PROTECTION

(71) Applicant: Taiwan Semiconductor Manufacturing Company, Ltd., Hsin-Chu (TW)

(72) Inventors: Ssu-Yu Liao, Hsinchu City (TW); Yu-Ju Hsu, Taoyuan County (TW); Tsu-Hui Su, Taipei City (TW); Chun-Hsiang Fan, Hsinchu City (TW); Ming-Hsi Yeh, Hsinchu (TW); Kuo-Bin Huang, Hsinchu County (TW)

(21) Appl. No.: 18/777,306

(22) Filed: Jul. 18, 2024

(51) Int. Cl. H01L 21/8234; H01L 21/311; H01L 27/088; H01L 29/06; H01L 29/16; H01L 29/423; H01L 29/66; H01L 29/775; H01L 29/786

(52) U.S. Cl. CPC H10D 84/038; H01L 21/31116; H10D 30/014; H10D 84/0151; H10D 84/83; H10D 30/43; H10D 30/6735; H10D 30/6757; H10D 62/121; H10D 62/83

(57) ABSTRACT

One aspect of the present disclosure pertains to forming a semiconductor stack over a substrate; patterning the semiconductor stack and the substrate to form semiconductor fins having semiconductor stack portions over base portions; depositing an isolation layer over the semiconductor fins; recessing the isolation layer to form an isolation structure surrounding base portions of the semiconductor fins; depositing a hard mask layer over the semiconductor fins and over the isolation structure, the hard mask layer includes bottom portions disposed on the isolation structure, sidewall portions disposed on sidewalls of the semiconductor fins, and top portions disposed on top surfaces of the semiconductor fins; performing a first etching process to recess the top portions of the hard mask layer; and performing a second etching process to planarize the bottom portions of the hard mask layer, thereby forming a hard mask structure with a planarized top surface over the isolation structure.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, there is an increased risk of unwanted coupling between semiconductor active regions and/or between semiconductor device components. Such unwanted coupling leads to capacitance degradation, current leakage, and performance loss. To address this, isolation structures such as shallow trench isolation (STI) structures are formed for proper isolation between active regions such as between fin active regions. However, during semiconductor manufacturing, the STI structures may be damaged, resulting in STI loss. For a gate-all-around transistor device, the STI loss may expose sidewall doped portions of a substrate. As a result, when a metal gate structure is formed over an active region, the metal gate structure may electrically couple to the exposed doped portions of the substrate. Such coupling introduces parasitic capacitance and/or current leakage, which degrades effective capacitance of the device and leads to performance loss. Further, the STI loss may lead to unwanted merging of source/drain epitaxial features, causing device defects.

Therefore, although existing methods of forming isolation structures have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a flow chart of a method to form a semiconductor device having a hard mask structure over an isolation structure, in portion or in entirety, according to an embodiment of the present disclosure.

FIGS. 2-11 illustrates cross-sectional views of a semiconductor device at intermediate stages of fabrication and processed in accordance with the method of FIG. 1, according to an embodiment of the present disclosure.

FIGS. 10A and 10B each illustrates cross-sectional views of a semiconductor to illustrate hard mask tuning considerations when forming a hard mask structure over an isolation structure, according to embodiments of the present disclosure.

FIG. 12 illustrates a flow chart of a method to form a semiconductor device having a hard mask structure over an isolation structure, in portion or in entirety, according to an embodiment of the present disclosure.

FIG. 13 illustrates a three-dimensional view of a semiconductor workpiece having a hard mask structure over an isolation structure and with lines A-A′, B-B′, and C-C′ cut across the workpiece.

FIGS. 14A, 15A, 16A, 17A, 18A, 19A, 20A, 21A, and 22A illustrate cross-sectional views of a semiconductor device cut along the lines A-A′ in FIG. 13 at intermediate stages of fabrication and processed in accordance with the method of FIG. 12 according to an embodiment of the present disclosure.

FIGS. 14B, 15B, 16B, 17B, 18B, 19B, 20B, 21B, and 22B illustrate cross-sectional views of a semiconductor device cut along the lines B-B′ in FIG. 13 at intermediate stages of fabrication and processed in accordance with the method of FIG. 12 according to an embodiment of the present disclosure.

FIGS. 14C, 15C, 16C, 17C, 18C, 19C, 20C, 21C, and 22C illustrate cross-sectional views of a semiconductor device cut along the lines C-C′ in FIG. 13 at intermediate stages of fabrication and processed in accordance with the method of FIG. 12 according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself limit the relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to a semiconductor device having an isolation structure with hard mask protection. The isolation structure may be a shallow trench isolation (STI) structure having a hard mask layer over it to suppress STI loss during semiconductor manufacturing. The hard mask layer is tuned to have a planar (or substantially planar profile), which has advantages over concave and/or convex profiles (as will be explained herein). The hard mask layer is also tuned to have a top surface just below a top surface of a doped substrate. As such, the hard mask layer enables effective capacitance boost by preventing gate-to-substrate coupling. The hard mask layer further allows effective removal of interposer layers when forming metal gates. The hard mask layer further prevents unwanted epitaxial bottom merging of source/drain features.

To illustrate the various aspects of the present disclosure, methods of forming a semiconductor device are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein.

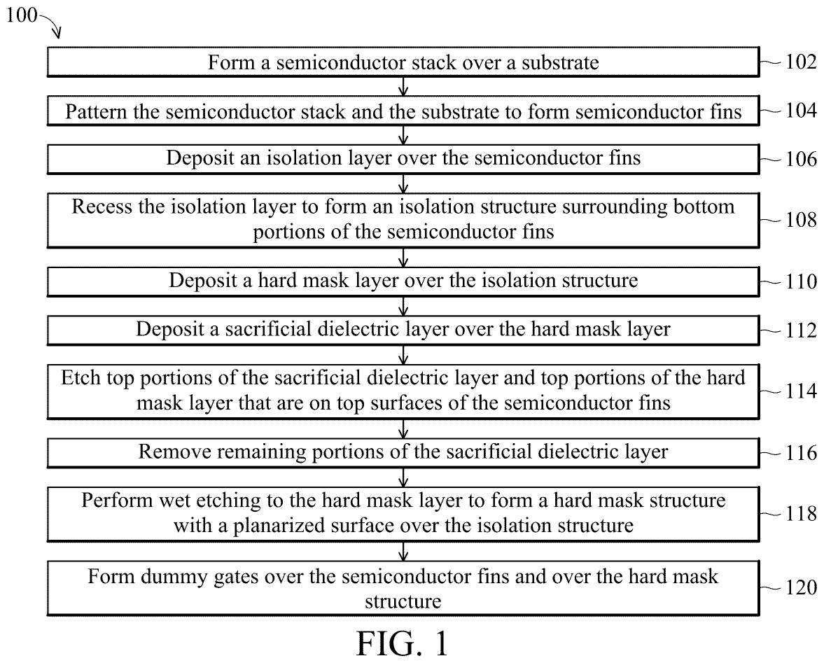

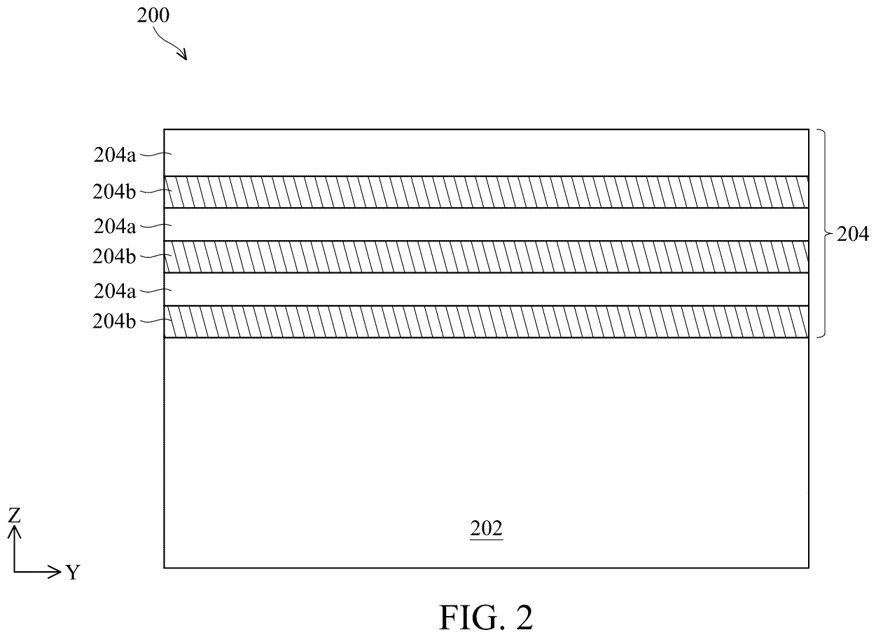

FIG. 1 illustrates a flow chart of a method 100 to form a semiconductor device having a hard mask structure over an isolation structure, in portion or in entirety, according to an embodiment of the present disclosure. Note that the hard mask structure and the isolation structure may be separately referred to as distinct features, or they may be collectively referred to as different portions of a larger isolation structure. FIGS. 2-11 illustrates cross-sectional views of a semiconductor device 200 at intermediate stages of fabrication and processed in accordance with the method 100 of FIG. 1. The method 100 is described below with reference to FIGS. 2-11. These figures have been simplified for the sake of clarity to better understand the inventive concepts of the present disclosure. Additional features can be added in the semiconductor device 200, and some of the features described below can be replaced, modified, or eliminated in other embodiments of the semiconductor device 200.

The semiconductor device 200 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

Referring now to FIG. 2, the method 100 at operation 102 begins forming a semiconductor device 200 by forming a semiconductor stack 204 over a substrate 202. The substrate 202 may be a silicon (Si) substrate, or a substrate having other semiconductor materials such as germanium (Ge), silicon carbide (SiC), silicon germanium (SiGe), or diamond. The substrate 202 may be doped with a p-type dopant such as boron or an n-type dopant such as phosphorus. In a further embodiment, the substrate 202 may be doped with nitrogen for growing defect-free silicon crystal stacks (e.g., semiconductor stack 204) or defect-free silicon crystal source/drain features (e.g., source/drain features 800 later described). The semiconductor stack 204 is then epitaxially grown over the substrate 202. The semiconductor stack 204 includes interleaved first and second semiconductor layers 204a and 204b. The first semiconductor layers 204a have a different material composition than the second semiconductor layers 204b. For example, each of the first semiconductor layers 204a is made of silicon and each of the second semiconductor layers 204b is made of silicon germanium. In an embodiment, the silicon and/or silicon germanium of the first and the second semiconductor layers 204a and 204b are undoped while the substrate 202 is doped. For example, the substrate 202 is made of silicon doped with boron while the first semiconductor layers 204a is made of pure silicon.

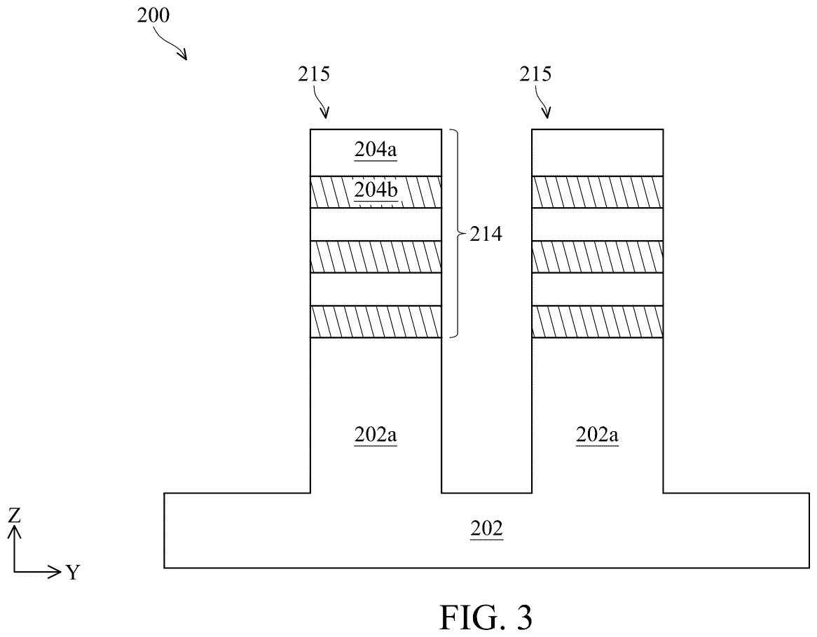

Referring now to FIG. 3, the method 100 at operation 104 patterns the semiconductor stack 204 and the substrate 202 to form semiconductor fins 215. Each of the semiconductor fins 215 includes a protruding portion 202a of the substrate 202 and a semiconductor stack portion 214 of the semiconductor stack 204. The semiconductor fins 215 may be formed by a patterning process that includes lithography and etching. In some embodiments, a lithography process forms a patterned mask layer that cover regions for forming the semiconductor fins 215, and an etching process uses the patterned mask layer as an etch mask to etch exposed portions of the patterned mask layer. The etching process forms recesses that separate and define the semiconductor fins 215.

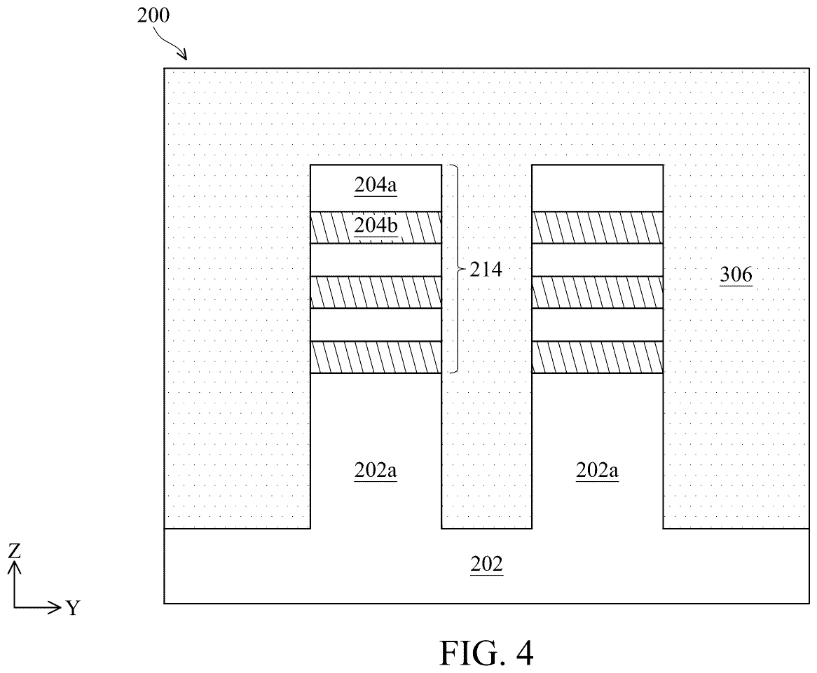

Referring to FIG. 4, the method 100 at operation 106 deposits an isolation layer 306 over the semiconductor fins 215. The isolation layer 306 lands on a top surface of the substrate 202, fills in the recesses between the semiconductor fins 215, and lands on a top surface of the semiconductor fins. In other words, the isolation layer 306 is overfilled to surround all exposed surfaces of the semiconductor fins 215. The isolation layer 306 may be deposited by any suitable deposition process, and the isolation layer 306 may include silicon oxide, silicon oxynitride, fluorine-doped silicate glass (FSG), a low-k dielectric, combinations thereof, and/or other suitable materials. In the present embodiment, the isolation layer 306 includes an oxide-based dielectric such as silicon oxide.

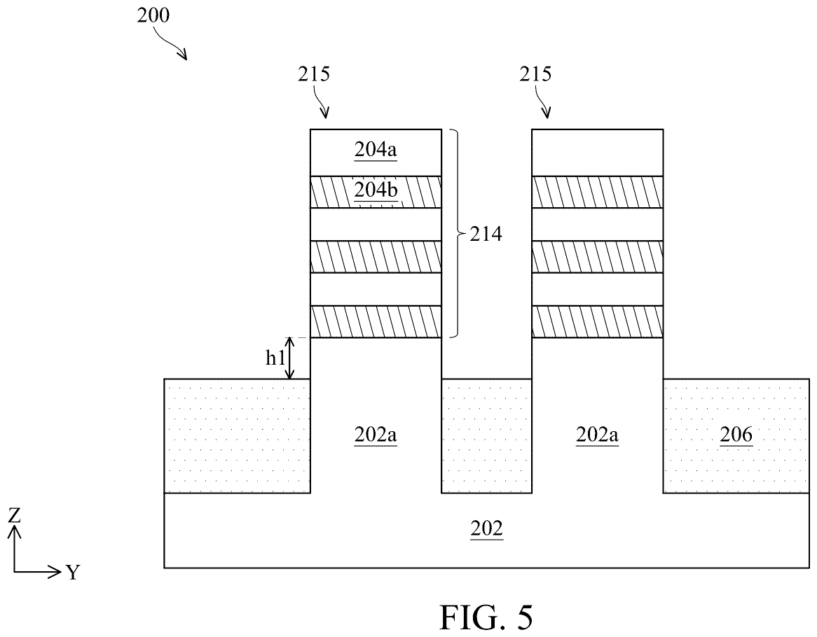

Referring to FIG. 5, the method 100 at operation 108 recesses the isolation layer 306 to form an isolation structure 206 surrounding bottom portions (e.g., protruding portions 202a) of the semiconductor fins 215. The isolation structure 206 may be formed by first performing a Chemical Mechanical Polish (CMP) to remove excess portions of the isolation layer 306 over top surfaces of the semiconductor fins 215. The remaining portions of the isolation layer 306 form isolation regions laterally between semiconductor fins 215. Next, the isolation regions are recessed in an etching step, so that the semiconductor stack portions 214 of the semiconductor fins 215 are over the top surfaces of the isolation regions. The resulting isolation regions form the isolation structure 206. In the present embodiment, the isolation structure 206 is a shallow trench isolation (STI) structure with an extended recess. As shown, a top surface of the isolation structure 206 is vertically offset from a top surface of the protruding portions 202a by a height h1. The height h1 accounts for the thickness of a later-formed hard mask layer. In an embodiment, the height h1 is greater than about 5 nm. If the height h1 is too small (e.g., smaller than 5 nm), there is a risk that the later-formed hard mask layer would block the bottommost second semiconductor layers 204b. This may lead to forming a defective metal gate for the bottommost channel of the later-formed semiconductor device 200. In an embodiment, the height h1 is greater than (or equal to) a thickness of one of the first or the second semiconductor layers 204a and 204b.

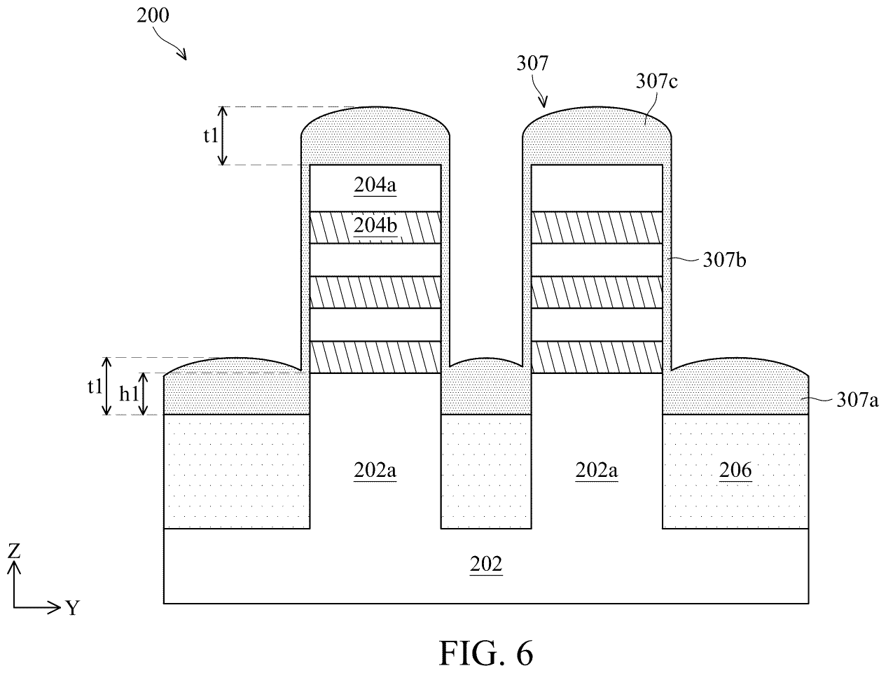

Referring to FIG. 6, the method 100 at operation 110 deposits a hard mask layer 307 over the isolation structure 206. The hard mask layer 307 includes bottom portions 307a disposed on the isolation structure 206, sidewall portions 307b disposed on sidewalls of the semiconductor fins 215, and top portions 307c disposed on top surfaces of the semiconductor fins 215. As shown, the bottom and top portions 307a and 307c have a greater thickness along the z direction than that of the sidewall portions 307b along the y direction. The bottom and top portions 307a and 307c are deposited to have convex rounded top surfaces. The convex rounded top surfaces provide suitable geometric effect for a later wet etching step. As shown, the bottom and top portions 307a and 307c may have a thickness t1 greater than the height h1. In an embodiment, the thickness t1 ranges between about 20 nm to about 30 nm. In an embodiment, top surfaces of the bottom portions 307a are between top and bottom surfaces of the bottommost second semiconductor layers 204b.

Still referring to FIG. 6, the hard mask layer 307 is deposited by chemical vapor deposition (CVD). The hard mask layer 307 has a different material composition from the isolation structure 206 to achieve desired etching selectivity and/or to achieve different isolation effects (e.g., to protect the isolation structure 206 from being etched in later fabrication steps). In the present embodiment, the hard mask layer 307 includes a nitride-based dielectric such as silicon nitride. In other embodiments, the hard mask layer 307 may include silicon oxynitride, silicon carbide, silicon oxycarbide, or silicon oxycarbonitirde.

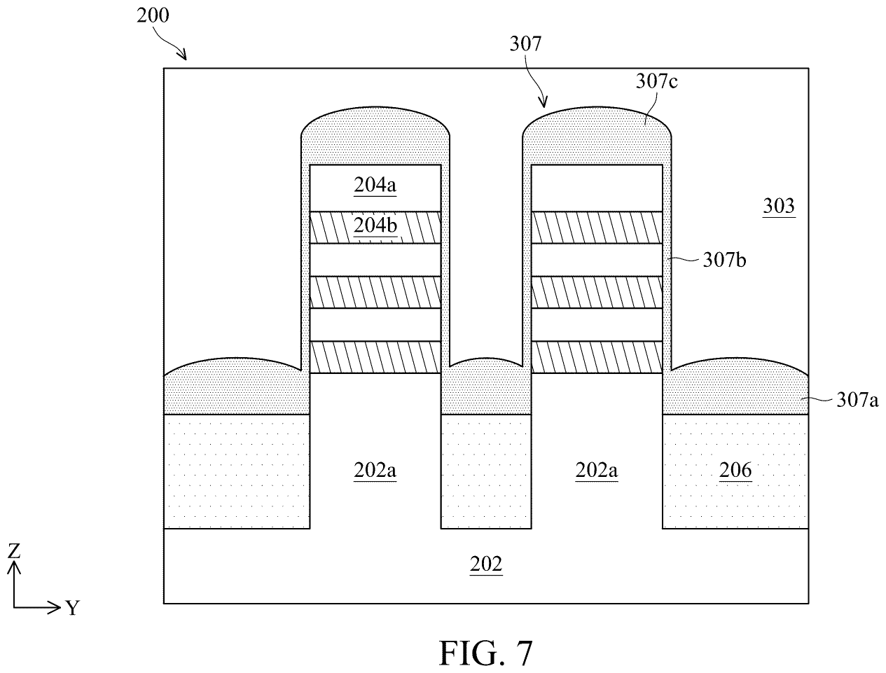

Referring to FIG. 7, the method 100 at operation 112 deposits a sacrificial dielectric layer 303 over the hard mask layer 307. The sacrificial dielectric layer 303 is used to pattern and prepare the deposited hard mask layer 307 for a later wet etching step. The sacrificial dielectric layer 303 is to be removed later. The sacrificial dielectric layer 303 may be a bottom antireflective coating (BARC) layer. The BARC layer is formed by spin-on coating, which is a cheaper process than CVD. In some instances, the BARC layer may include silicon-containing polymers, carbon-containing polymers, or spin-on carbon (SOC). In the depicted embodiments, the sacrificial dielectric layer 303 fills in the gaps between the semiconductor fins 215 and a top surface of sacrificial dielectric layer 303 (e.g., BARC layer) is higher than a top surface of the top portions 307c of the hard mask layer 307.

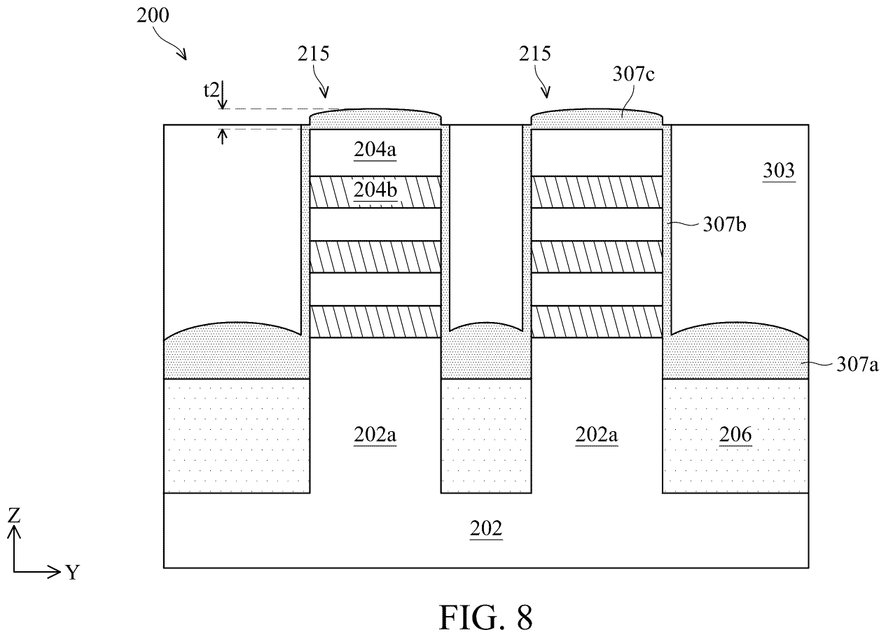

Referring to FIG. 8, the method 100 at operation 114 etches top portions the sacrificial dielectric layer 303 and top portions 307c of the hard mask layer 307 that are on top surfaces of the semiconductor fins 215. In the depicted embodiment, the sacrificial dielectric layer 303 and top portions 307c of the hard mask layer 307 are simultaneously and anisotrpoically etched back (or recessed) to have reduced heights. The operation 114 may include performing a dry etch process that uses nitrogen plasma, hydrogen plasma, argon (Ar), or a combination thereof. In the present embodiment, the operation 114 includes directional plasma etching using NH₃ and H₂ as plasma etching gases. In the present embodiment, the sacrificial dielectric layer 303 is etched back at a greater rate than the hard mask layer 307 due to their compositions having different etchant selectivity. As a result, after operation 114, the top portions 307c of the hard mask layer 307 may still remain but at a reduced thickness t2.

Still referring to FIG. 8, it is emphasized that the operation 114 does not completely remove the top portions 307c. If the top portions 307c is completely removed, a later wet etching step may damage or reduce the thickness of the topmost semiconductor layers 204a. By still having the top portions 307c (but at the reduced thickness t2), the later wet etching step will simply remove the remaining top portions 307c without damaging or reducing the thickness of the topmost semiconductor layers 204a. In an embodiment, the thickness t2 ranges between about 1 nm to about 5 nm. In an embodiment, the thickness t2 is about equal to a thickness of the sidewall portions 307b along the y direction.

Still referring to FIG. 8, in alternative embodiments, the operation 114 does completely remove the top portions 307c. In these embodiments, the topmost semiconductor layers 204a may be formed to be thicker than the rest of the semiconductor layers 204a. This accounts for any subsequent etching that causes thickness reduction. In even further embodiments (as shown), the operation 114 does not completely remove the top portions 307c but the topmost semiconductor layers 204a is still formed to be thicker than the rest of the semiconductor layers 204a. This accounts for added protection in case that the remaining top portions 307c does not provide enough wet etching protection.

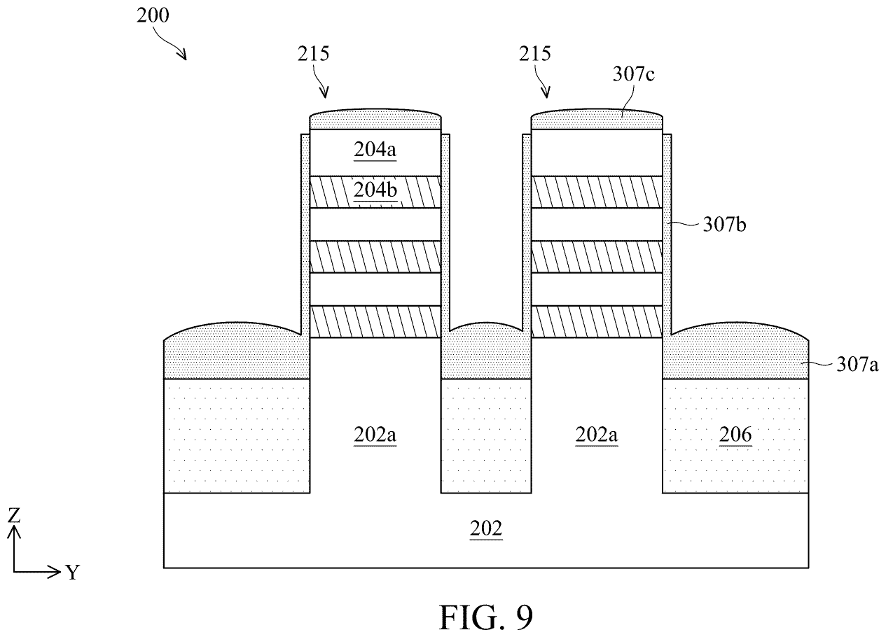

Referring to FIG. 9, the method 100 at operation 116 removes remaining portions of the sacrificial dielectric layer 303. As shown in FIG. 9, the sacrificial dielectric layer 303 is completely and selectively removed. For example, the sacrificial dielectric layer 303 may be removed through plasma ashing or wet stripping. The plasma ashing or wet stripping completely removes the sacrificial dielectric layer 303 without substantially affecting the hard mask layer 307. However, in some embodiments (like as shown), top sidewall portions 307b may be slightly etched; therefore the topmost semiconductor layers 204a may have top sidewall portions that are slightly exposed.

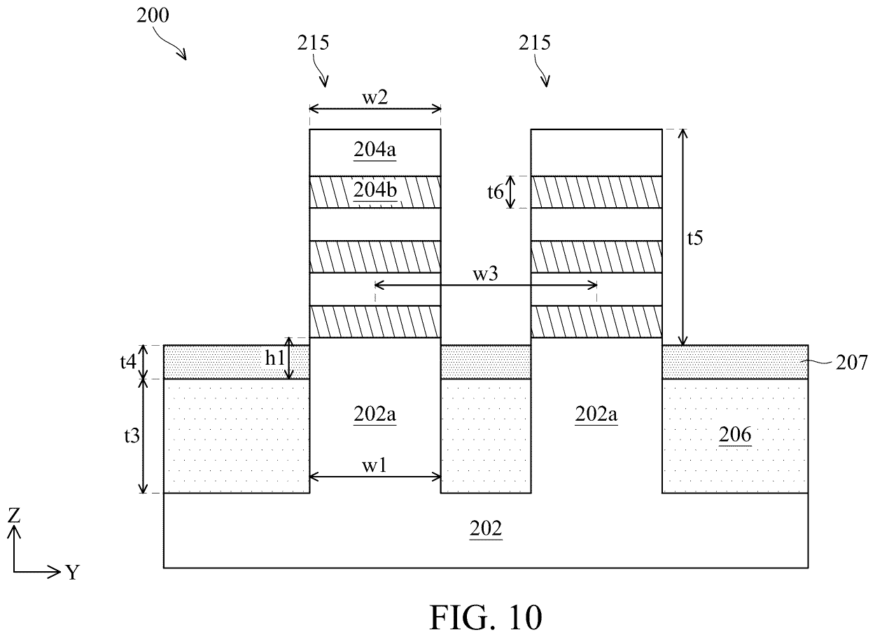

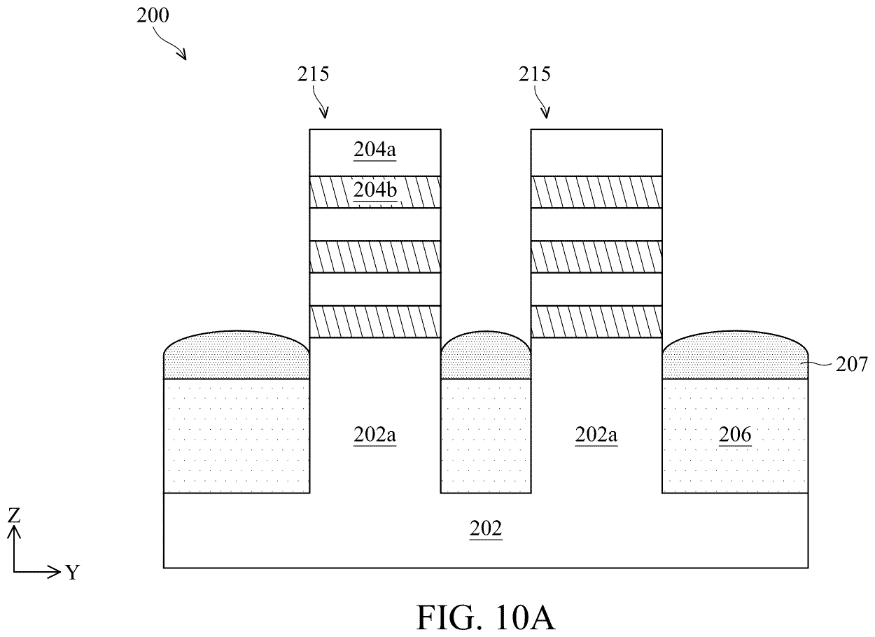

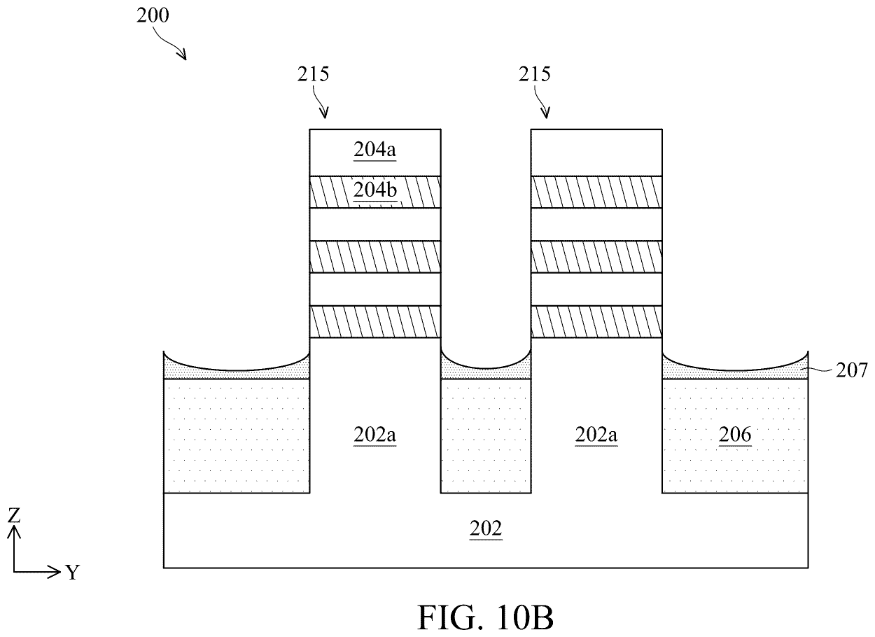

Referring to FIG. 10, the method 100 at operation 118 performs wet etching to the hard mask layer 307 to form a hard mask structure 207 with a planarized surface over the isolation structure 206. In the present embodiment, the wet etching includes isotropic wet etching using phosphoric acid (H₃PO₄) as an etching agent. Phosphoric acid has a high SiN to Si/SiO₂ selectivity, which minimizes damage to the semiconductor stacks 204 of the semiconductor fins 215. As shown, the wet etching simultaneously removes the remaining top portions 307c and the sidewall portions 307b of the hard mask layer 307. Further, the wet etching also simultaneously tunes the convex profile of the bottom portions 307a into a planar profile. Due to the bottom portions 307a having convex rounded top surfaces, isotropic wet etching will etch areas of large contact area (middle portion of convex top surface) at a greater rate than areas of small contact area (edge portions of the convex top surface). This geometric effect allows the bottom portions 307a to be etched until it forms a planarized top surface. As a result, a hard mask structure 207 is formed over the isolation structure 206. In an embodiment, top surfaces of the hard mask structure 207 and the isolation structure 206 are parallel (or substantially parallel) to each other.

Note that planarizing the bottom portions 307a by wet etching is not a trivial process. Referring to FIGS. 10A and 10B, if the wet etching is not tuned or controlled properly, the hard mask structure 207 may be formed to have a convex profile (FIG. 10A) or a concave profile (FIG. 10B), both of which is undesired. For example, referring to FIG. 10A, if the bottom portions 307a are under-etched due to timing or other parameter effects, the resulting hard mask structure 207 would still have convex rounded top surfaces. The convex rounded top surfaces would cause worsened interposer residue by blocking the bottommost semiconductor layers 204b. This may lead to forming a defective metal gate for the bottommost channel of the later-formed semiconductor device 200. For another example, referring to FIG. 10B, if the bottom portions 307a are over-etched due to timing or other parameter effects, the resulting hard mask structure 207 would have concave rounded top surfaces. The concave rounded top surfaces worsens isolation protection, which may lead to parasitic capacitance coupling or leakage effects after metal gates are formed.

Referring back to FIG. 10, the resulting semiconductor device 200 includes an isolation structure 206 having a thickness t3, a hard mask structure 207 having a thickness t4, semiconductor stack portions 214 having a thickness t5, individual first and/or second semiconductor layers 204a and 204b having thicknesses t6, protruding portions 202a of the substrate 202 having a sheet width w1, the semiconductor fins 215 having a top width w2, and adjacent semiconductor fins 215 having a pitch width w3. In an embodiment, the thickness t3 ranges between about 30 nm to about 100 nm. In an embodiment, the thickness t4 ranges between about 1 nm to about 50 nm. In an embodiment, the thickness t5 ranges between about 5 nm to about 100 nm. In an embodiment, the thickness t6 ranges between about 1 to about 20 nm. In an embodiment the width w1 ranges between about 5 nm to about 200 nm. In an embodiment, the width w2 ranges between about 2 nm to about 150 nm. Although not shown, the width w1 may be greater than the width w2 due to tapering profiles of the semiconductor fins 215. In an embodiment the width w3 ranges between about 5 nm to about 1 μm.

Still referring to FIG. 10, the thickness t3 is greater than the thickness t4 such that the isolation structure 206 provides the bulk of the isolation between semiconductor fins 215. The thickness t4 needs to only be thick enough to prevent damage or loss to the isolation structure 206. In an embodiment, the ratio of t3 to t4 ranges between about 2 to about 30. If the ratio of t3 to t4 is less than 2, the hard mask structure 207 may be too thick, raising unnecessary manufacturing costs. If the ratio of t3 to t4 is greater than 30, the hard mask structure 207 may be too thin to provide isolation structure protection. Note also that the thickness t4 is close to but less than the height h1. In this way, there is sufficient hard mask protection to surround top portions of the protruding portions 202a without blocking the bottommost semiconductor layers 204b. The difference between the thickness t4 to the height h1 may range between 1 nm to 5 nm.

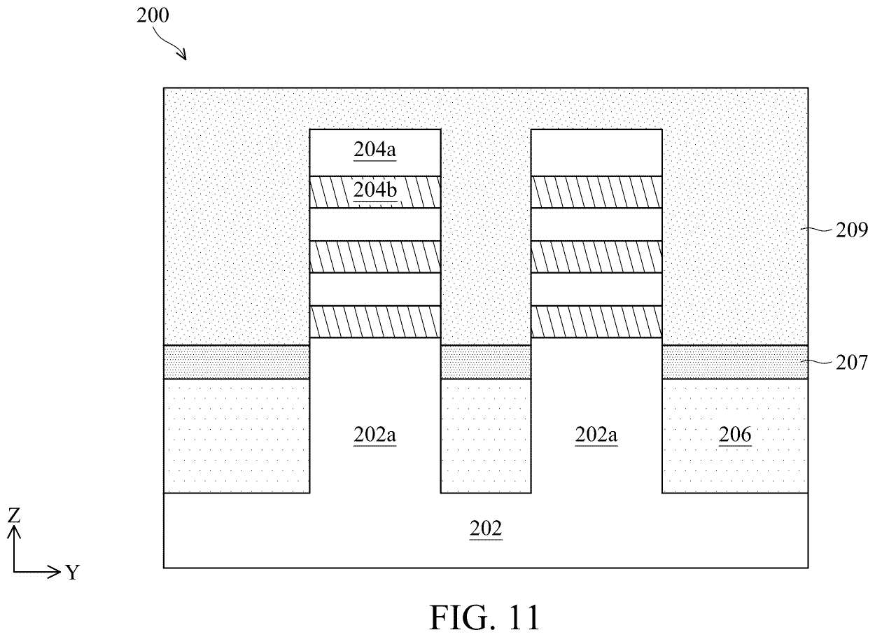

Referring now to FIG. 11, the method 100 at operation 120 forms dummy gate stacks 209 over the semiconductor fins 215 and over the hard mask structure 207. As further described below, the dummy gate stacks 209 are formed over channel regions of the semiconductor fins 215. Each of the dummy gate stacks 209 may be made of polysilicon and surround the semiconductor stack portions 214 of the semiconductor fins 215. Although not shown, the dummy gate stacks 209 may include various layers, such as dummy gate electrode layers, dummy gate dielectric layers, and/or dummy hard mask layers.

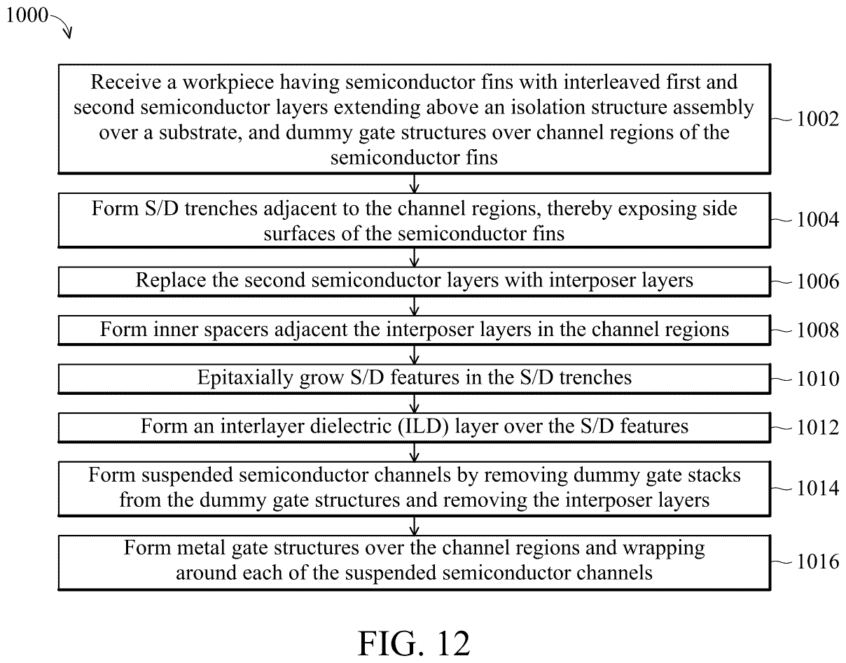

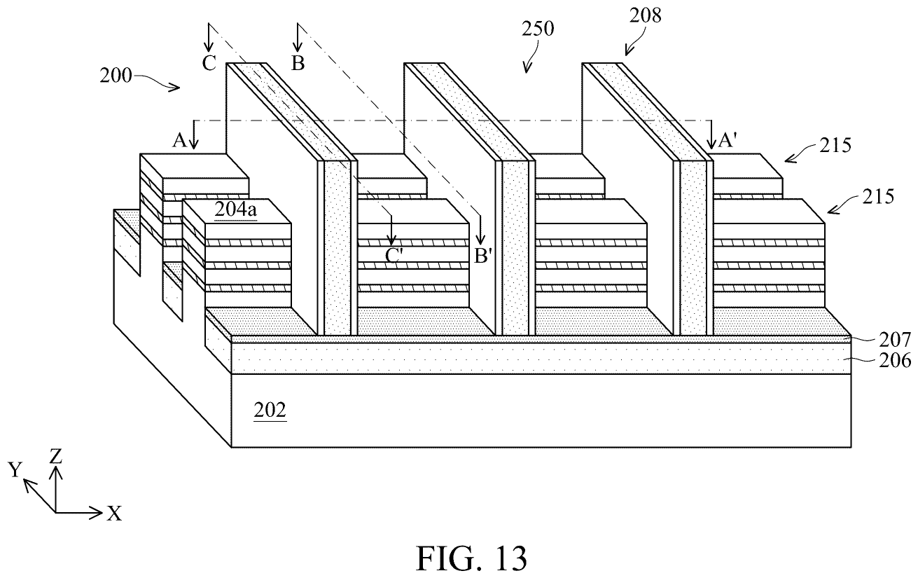

FIG. 12 illustrates a flow chart of a method 1000 to form a semiconductor device 200 having a hard mask structure 207 over an isolation structure 206, in portion or in entirety, according to an embodiment of the present disclosure. In an embodiment, the semiconductor device 200 at the end of method 100 is received at the beginning of method 1000, and the received semiconductor device 200 continues to be processed according to the method 1000. The method 1000 is described below with reference to FIGS. 13, 14A-22A, 14B-22B, and 14C-22C. These figures have been simplified for the sake of clarity to better understand the inventive concepts of the present disclosure. Additional features can be added in the semiconductor device 200, and some of the features described below can be replaced, modified, or eliminated in other embodiments of the semiconductor device 200.

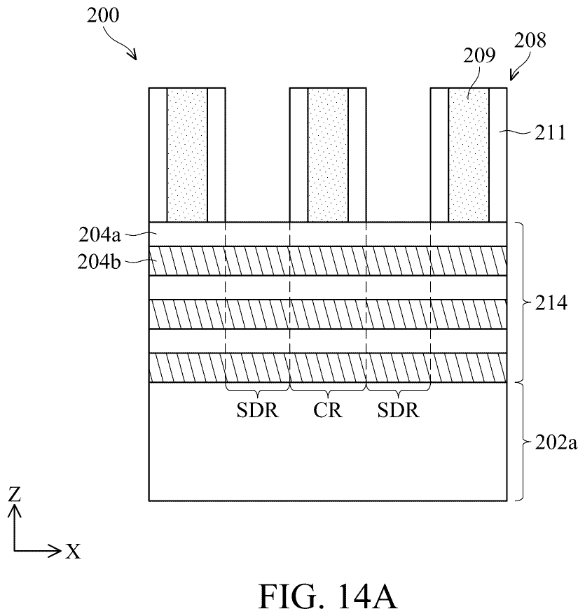

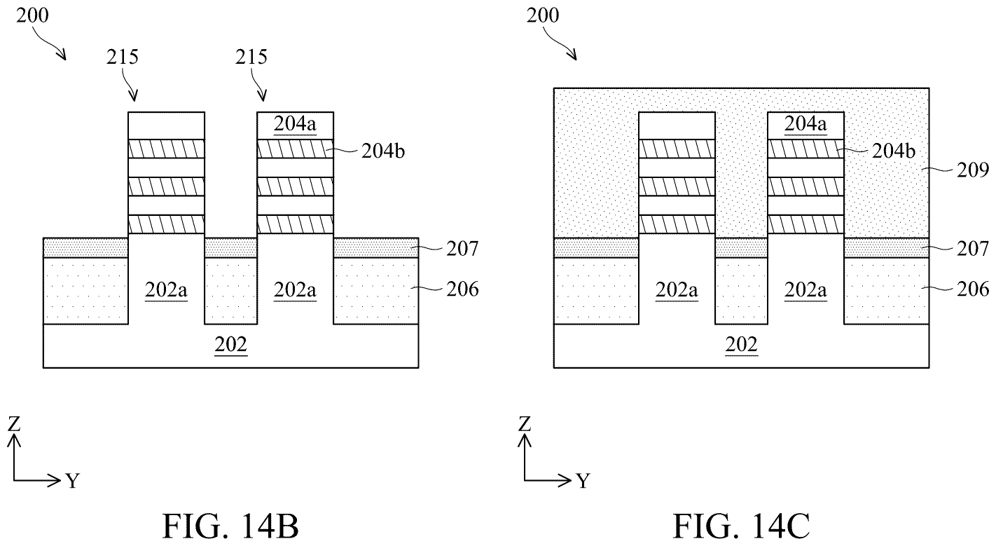

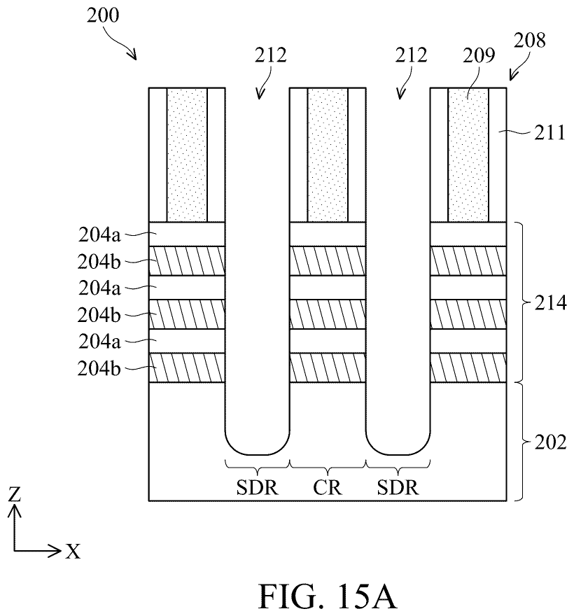

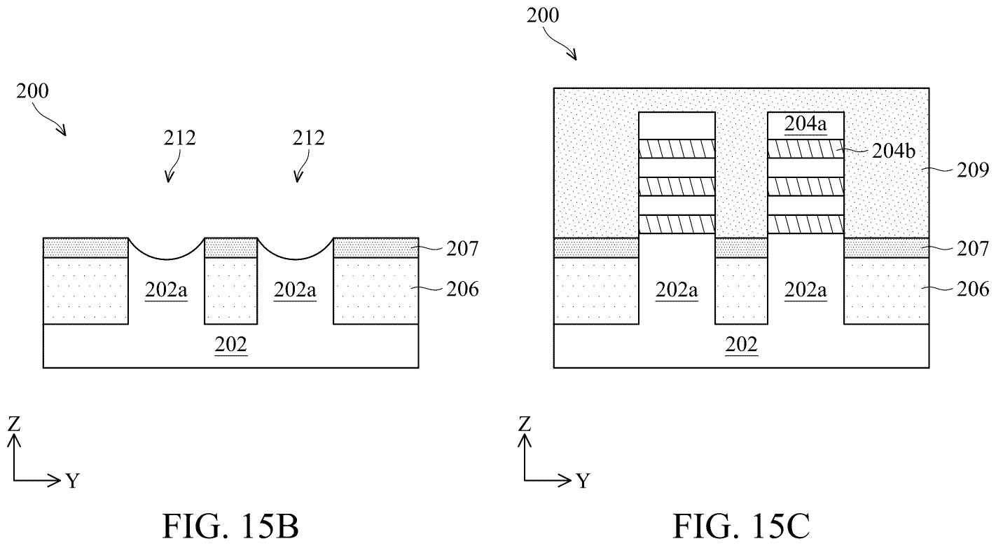

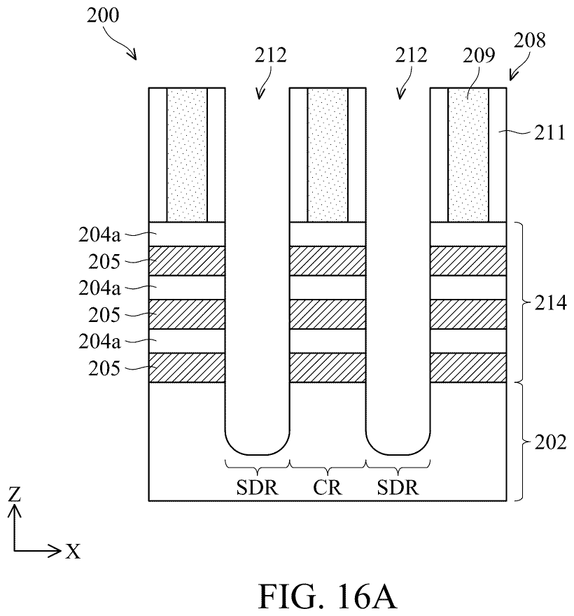

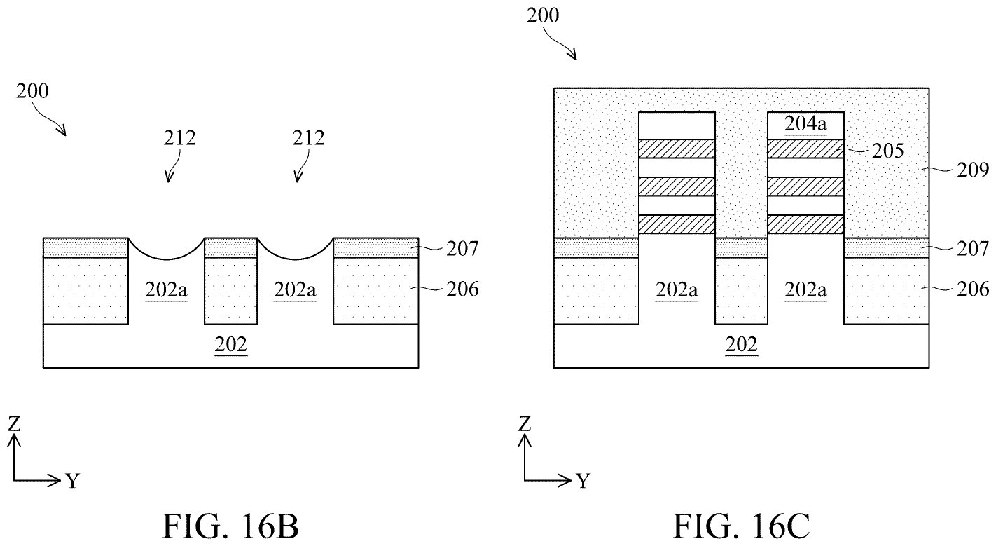

FIG. 13 illustrates a three-dimensional view of a semiconductor workpiece 250 having a hard mask structure 207 over an isolation structure 206 and with lines A-A′, B-B′, and C-C′ cut across the workpiece. The semiconductor workpiece 250 corresponds to the semiconductor device 200 at the end of method 100 (e.g., at the stage illustrated in FIG. 11). The line A-A′ cuts lengthwise in the x direction along a semiconductor fin 215 and across multiple dummy gate structures 208. The line B-B′ cuts lengthwise in the y direction across multiple source/drain regions (SDR) of the semiconductor fins 215. The line C-C′ cuts lengthwise in the y direction across a dummy gate stack 209 of a dummy gate structure 208. FIGS. 14A-22A, 14B-22B, and 14C-22C illustrate cross-sectional views of a semiconductor device 200 cut along the lines A-A′, B-B′, and C-C′ respectively at intermediate stages of fabrication and processed in accordance with the method 1000 of FIG. 12. FIGS. 14A, 14B, and 14C are at a same stage of fabrication, FIGS. 15A, 15B, and 15C are at a same stage of fabrication, FIGS. 16A, 16B, and 16C are at a same stage of fabrication, and so on.

Referring now to FIG. 13 and FIGS. 14A-14C collectively, the method 1000 at operation 1002 receives a workpiece 250 of a semiconductor device 200. The workpiece 250 may be formed by the method 100 previously described. The workpiece 250 includes semiconductor fins 215 with interleaved first and second semiconductor layers 204a and 204b, where the semiconductor fins 215 extends above an isolation structure assembly over a substrate 202. The isolation structure assembly includes an isolation structure 206 and a hard mask structure 207 over the isolation structure 206. The workpiece further includes dummy gate structures 208 having dummy gate stacks 209 and gate spacers 211 formed over channel regions CR of the semiconductor fins 215. The semiconductor fins 215 (also referred to as active regions or fin active regions) extend lengthwise in the x direction, and the dummy gate structures 208 extend lengthwise in the y direction.

Referring to FIG. 14A, the channel regions CR are regions of the semiconductor fins 215 underneath the dummy gate stacks 209. The source/drain (S/D) regions SDR are regions of the semiconductor fins 215 adjacent the channel regions CR and extending between the dummy gate structures 208. Each of the dummy gate structures 208 includes a dummy gate stack 209 and gate spacers 211 over sidewalls of the dummy gate stack 209. The dummy gate stack 209 may be made of polysilicon and the gate spacers 211 may be made of silicon oxide, silicon nitride, silicon oxycarbide, silicon oxycarbonitride, silicon carbonitride, metal nitride, or a suitable dielectric material. Referring to FIGS. 14B-14C, since the dummy gate structure 208 are disposed only over channel regions CR and not over the S/D regions SDR, only FIG. 14C shows a dummy gate stack 209 covering the semiconductor fins 215. Note that FIG. 14C illustrates a cross-sectional view that corresponds to the semiconductor device 200 in FIG. 11.

Referring now to FIGS. 15A-15C collectively, the method 1000 at operation 1004 forms S/D trenches 212 in the S/D regions adjacent to the channel regions CR. The S/D trenches 212 expose side surfaces of remaining portions of the semiconductor fins 215 (i.e., portions in the channel regions CR). The S/D trenches 212 may be formed by a dry etching process, a wet etching process, other suitable etching process, or combinations thereof. In some embodiments, the etching process is a multi-step etch process. For example, the etching process may include alternative etchants to separately and alternately remove semiconductor layers 204a and semiconductor layers 204b. In some embodiments, parameters of the etching process are configured to selectively etch semiconductor stack portions 214 with minimal (to no) etching of dummy gate structures 208 (i.e., dummy gate stacks 209 and gate spacers 211). In some embodiments, a lithography process is performed to form a patterned mask layer that covers dummy gate structures 208, and the etching process uses the patterned mask layer as an etch mask when forming the S/D trenches 212.

Notably, referring to FIG. 15B, due to the presence of the hard mask structure 207, the etching process to form the S/D trenches 212 does not cause damage or loss to the isolation structure 206. For example, in the case that the isolation structure 206 includes silicon oxide and the hard mask structure 207 includes silicon nitride, an etchant may be chosen with high selectivity to etch silicon or silicon oxide, but not silicon nitride. As the S/D regions SDR are being etched, the silicon nitride hard mask structure 207 prevents the silicon oxide isolation structure 206 from being etched or damaged. With the isolation structure 206 intact, the bottom protruding portions 202a of adjacent semiconductor fins 215 are prevented from getting too close to each other. If they get too close, there may be unwanted epitaxial merge in a later step when growing S/D features over the bottom protruding portions 202a.

Referring now to FIGS. 16A-16C collectively, the method 1000 at operation 1006 replaces the second semiconductor layers 204b with interposer layers 205. The operation 1006 may include etching to completely remove the second semiconductor layers 204b with minimal (to no) etching of the first semiconductor layers 204a. Then, interposer layers 205 are formed in the space left behind by the removed second semiconductor layers 204b. The interposer layers 205 may be formed by an interposer deposition process and an interposer etching process. For example, an interposer deposition process is performed to fill a dielectric material in the S/D trenches 212. The dielectric material seeps into the gaps left behind by the removed second semiconductor layers 204b, thereby filling in the gaps. Then, an interposer etching process is performed to selectively etch the dielectric material to form the interposer layers 205. The interposer etching process may be a dry etching process to remove the excess dielectric material in the S/D trenches 212 and outside of the channel regions CR. In the present embodiment, the dielectric material of the interposer layers 205 is an oxide-based dielectric such as silicon oxide.

The interposer layers 205 will later be removed at a later channel-release stage when forming metal gates. Note that in other embodiments, the second semiconductor layers 204b are not replaced with the interposer layers 205. Instead, the second semiconductor layers 204b remain until they are removed at the later channel-release stage. For the present embodiment, by replacing the second semiconductor layers 204b with interposer layers 205, there will be reduced damage to the silicon channels and the S/D features during channel-release. This is because the interposer layers 205 can be selectively removed with no or little semiconductor residue (e.g., no SiGe residue), as opposed to directly removing the second semiconductor layers 204b at the channel-release stage.

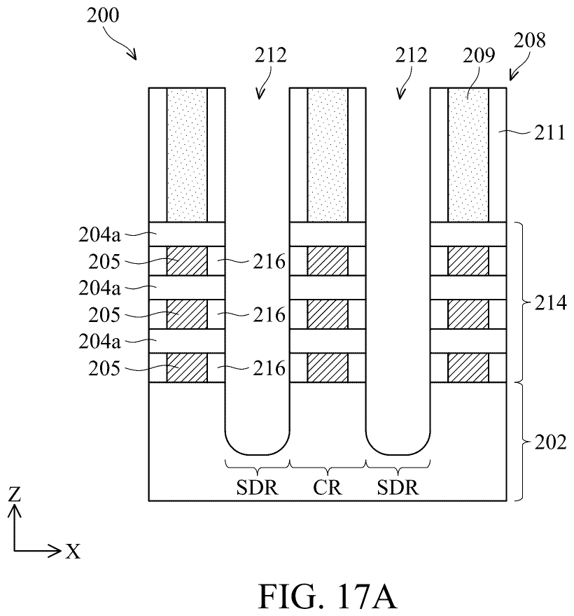

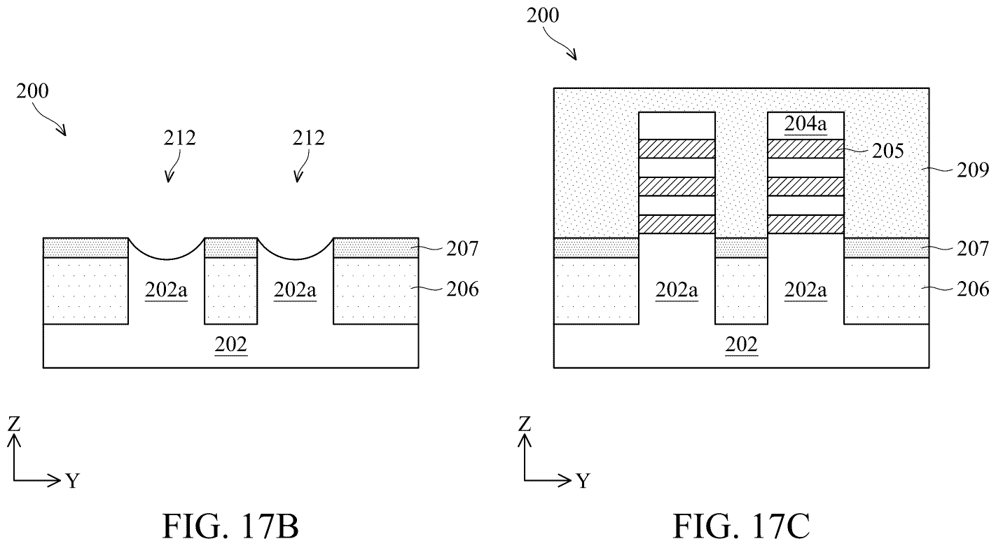

Referring now to FIGS. 17A-17C collectively, the method 1000 at operation 1008 forms inner spacers 216 adjacent to the interposer layers 205 in the channel regions CR. The inner spacers 216 may be formed by any suitable process. In an embodiment, a side etch process is performed to selectively etch sidewalls of the interposer layers 205 without etching (or substantially etching) the first semiconductor layers 204a. In other words, the side etch process is configured to laterally etch (e.g., along the x direction) interposer layers 205, thereby reducing a length of the interposer layers 205 along the x direction. The side etch process may be performed after forming the interposer layers 205. Alternatively, the side etch process may be performed as part of forming the interposer layers 205. The side etch process is a dry etching process, a wet etching process, other suitable etching process, or combinations thereof. After the side etch process is performed, air gaps are formed under each of the first semiconductor layers 204a. Then, inner spacers 216 are formed in each of the air gaps. The inner spacers 216 are disposed directly below the gate spacers 211, and they may be substantially vertically aligned with the gate spacers 211 along the z direction.

The inner spacers 216 may be formed by a spacer deposition process and a spacer etching process. For example, a spacer deposition process is performed to form a spacer layer over the dummy gate structures 208 and over features defining the S/D trenches 212 (e.g., semiconductor layers 204a, interposer layers 205, and substrate 202). The spacer layer partially (and, in some embodiments, completely) fills the S/D trenches 212. The spacer deposition process is configured to ensure that the spacer layer fills the air gaps between semiconductor layers 204a and between semiconductor layers 204a and substrate 202 under gate spacers 211. A spacer etching process is then performed that selectively etches the spacer layer to form inner spacers 216 as depicted in FIG. 17A with minimal (to no) etching of semiconductor layers 204a, dummy gate stacks 209, and gate spacers 211. The spacer layer (and thus inner spacers 216) includes a material that is different than a material of semiconductor layers 204a and a material of gate spacers 211 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

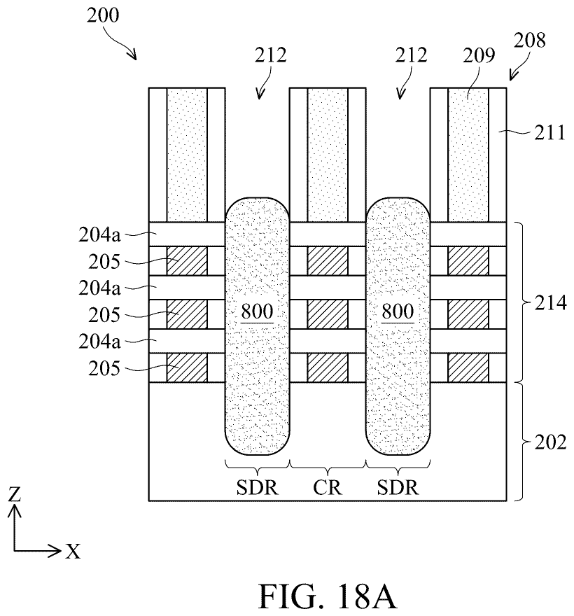

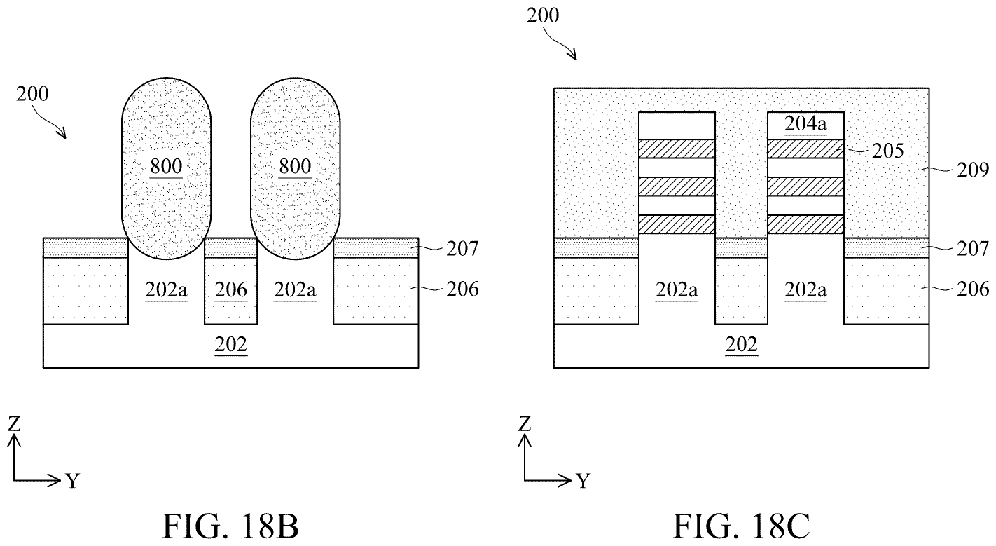

Referring now to FIGS. 18A-18C collectively, the method 1000 at operation 1010 epitaxially grows S/D features 800 in the S/D trenches 212 and over the protruding portions 202a of the semiconductor fins 215. The S/D features 800 may include n-type S/D features that correspond with n-type GAA transistor regions or p-type S/D features that correspond with p-type GAA transistor regions. The S/D features 800 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the substrate 202 (or protruding portion 202a thereof) and/or semiconductor stack portions 214 (in particular, semiconductor layers 204a). Epitaxial S/D features 800 are doped with n-type dopants and/or p-type dopants. In some embodiments, for the n-type GAA transistors, epitaxial S/D features 800 include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, epitaxial S/D features 800 include silicon germanium or germanium and can be doped with boron, other p-type dopant, or combinations thereof (for example, forming Si:Ge:B epitaxial source/drain features).

In some embodiments, epitaxial S/D features 800 include materials and/or dopants that achieve desired tensile stress and/or compressive stress in respective channel regions CR. In some embodiments, epitaxial S/D features 800 are doped during deposition by adding impurities to a source material of the epitaxy process (i.e., in-situ). In some embodiments, epitaxial S/D features 800 are doped by an ion implantation process subsequent to a deposition process. In some embodiments, annealing processes (e.g., rapid thermal annealing (RTA) and/or laser annealing) are performed to activate dopants in epitaxial S/D features 800 and/or other source/drain regions (for example, heavily doped source/drain regions and/or lightly doped source/drain (LDD) regions). In some embodiments, epitaxial S/D features 800 are formed in separate processing sequences that include, for example, masking p-type GAA transistor regions when forming epitaxial S/D features 800 in n-type GAA transistor regions and masking n-type GAA transistor regions when forming epitaxial S/D features 800 in p-type GAA transistor regions.

In some embodiments (not shown), epitaxial S/D features 800 are formed to include more than one epitaxial layer. For example, each of the S/D features 800 includes an inner heavily doped layer and an outer lightly doped layer (or layers). In one embodiment, the outer lightly doped layer is first epitaxially grown in the S/D trenches 212 from side surfaces of the semiconductor layers 204a and the substrate 202. Then, the inner heavily doped layer is epitaxially grown from the outer lightly doped layer to fill the S/D trenches 212. The S/D features 800 may grow to a height above the topmost first semiconductor layers 204a and between gate spacers 211 of different dummy gate structures 208. As shown in FIG. 18B, the S/D features 800 are grown over the hard mask structure 207 and the isolation structure 206.

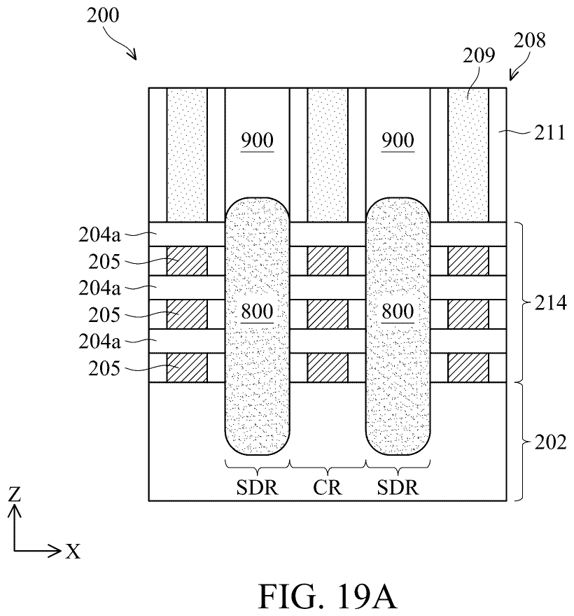

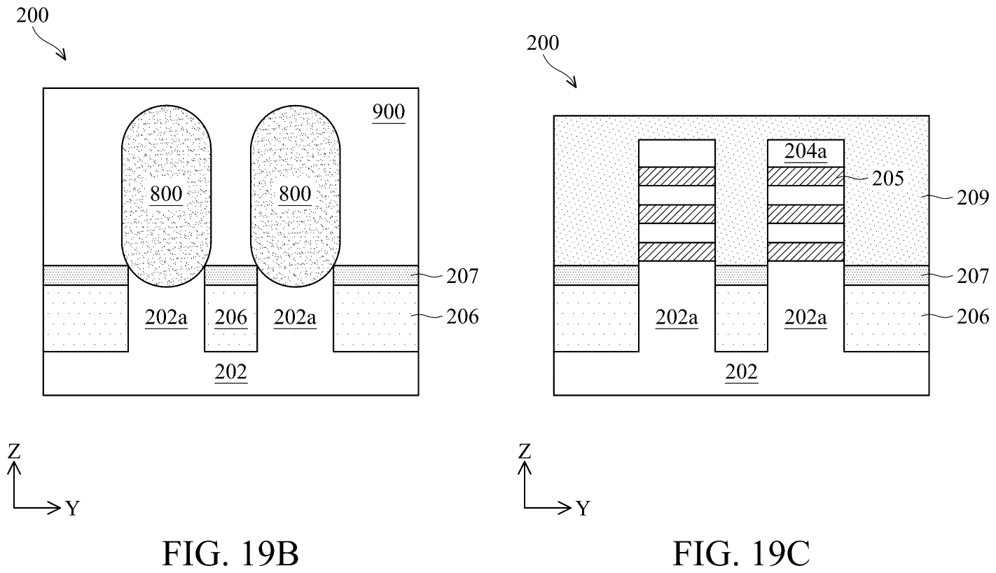

Referring now to FIGS. 19A-19C collectively, the method 1000 at operation 1012 forms an interlayer dielectric (ILD) layer 900 over the S/D features 800. As shown in FIG. 19A, the ILD layer 900 also fills the space between adjacent dummy gate structures 208. The ILD layer 900 may be formed by a deposition process (such as CVD, PVD, ALD, HDPCVD, MOCVD, RPCVD, PECVD, LPCVD, ALCVD, APCVD, plating, other suitable methods, or combinations thereof). In some embodiments, ILD layer 900 is formed by a flowable CVD (FCVD) process that includes, for example, depositing a flowable material (such as a liquid compound) over the device 200 and converting the flowable material to a solid material by a suitable technique, such as thermal annealing and/or ultraviolet radiation treating.

The ILD layer 900 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Acrogel, amorphous fluorinated carbon, Parylene, BCB, SILK (Dow Chemical, Midland, Michigan), polyimide, other low-k dielectric material, or combinations thereof. In the depicted embodiment, ILD layer 900 is a dielectric layer that includes a low-k dielectric material (generally referred to as a low-k dielectric layer). ILD layer 900 can include a multilayer structure having multiple dielectric materials. In some embodiments, a contact etch-stop layer (CESL) (not shown) is disposed between ILD layer 900 and the hard mask structure 207, S/D features 800, and gate spacers 211. The CESL includes a material different than ILD layer 900, such as a dielectric material that is different than the dielectric material of ILD layer 900. For example, where ILD layer 900 includes silicon oxide or a low-k dielectric material, the CESL includes silicon and nitrogen, such as silicon nitride or silicon oxynitride. Subsequent to the deposition of ILD layer 900 and/or the CESL, a CMP process and/or other planarization process may be performed until reaching (exposing) a top portion (or top surface) of dummy gate stacks 209.

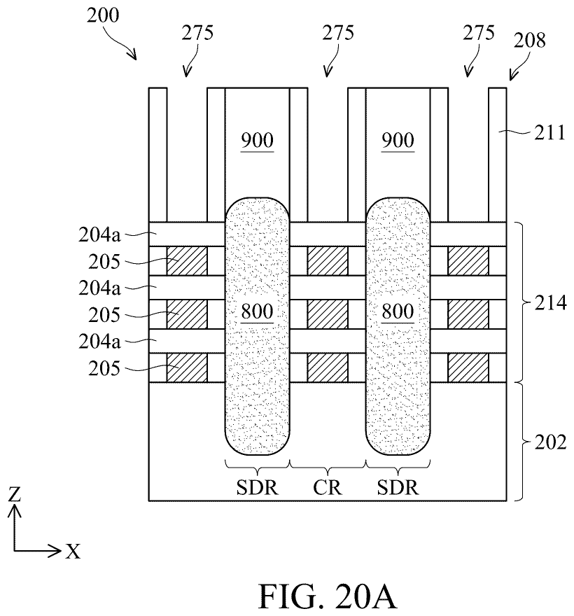

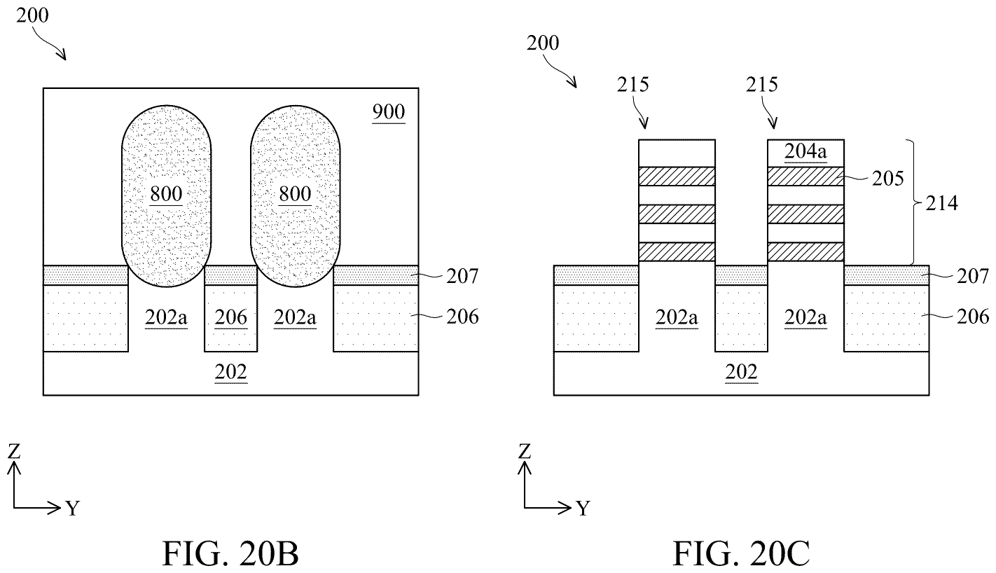

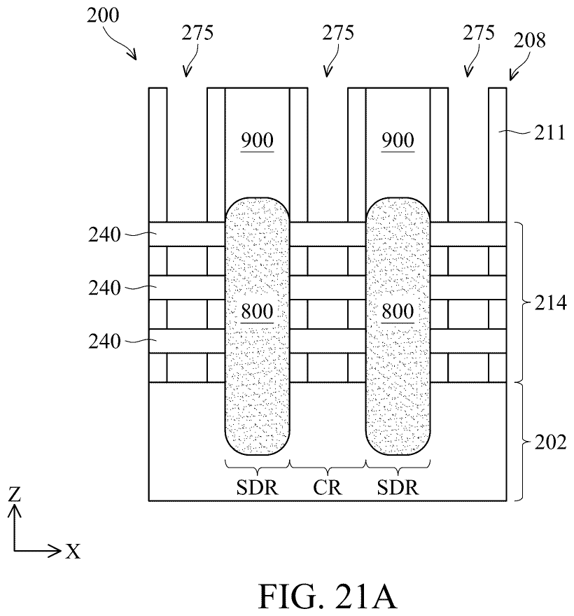

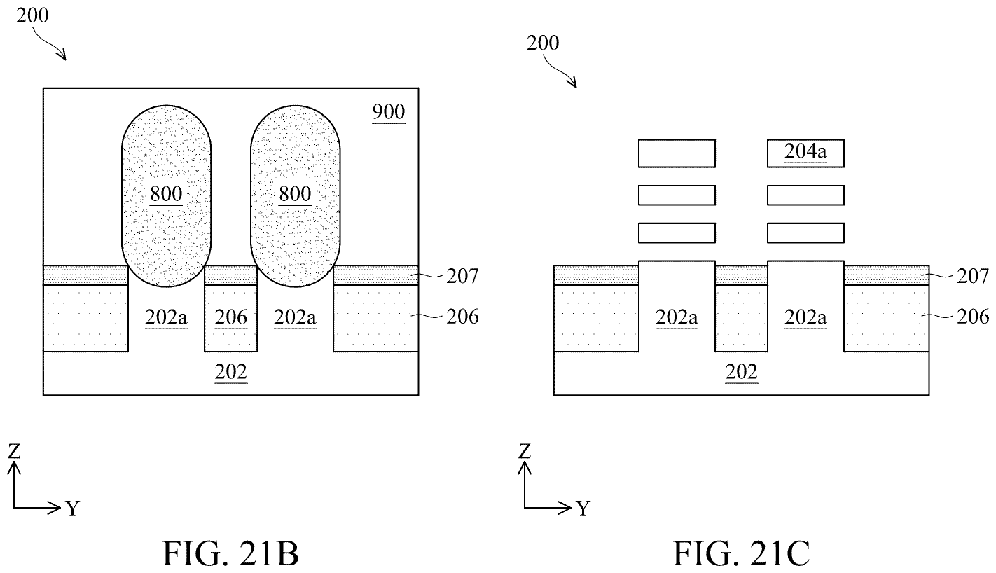

Referring now to FIGS. 20A-20C and 21A-21C collectively, the method 1000 at operation 1014 forms suspended semiconductor channels 240 by removing dummy gate stacks 209 from the dummy gate structures 208 and removing the interposer layers 205.

First, as shown in FIGS. 20A-20C, the operation 1014 removes the dummy gate stacks 209 to expose the channel regions CR under the dummy gate stacks 209. The dummy gate stacks 209 are removed by a suitable etching process, thereby resulting in gate trenches 275 and exposing the semiconductor stack portions 214. The etching process is designed with etchant to selectively remove the dummy gate stacks 209. In the depicted embodiment, an etching process completely removes dummy gate stacks 209 to expose surfaces of the semiconductor layers 204a and interposer layers 205 in the y-z plane (see FIG. 20C). The etching process is a dry etching process, a wet etching process, other suitable etching process, or combinations thereof. In some embodiments, the etching process is a multi-step etch process. For example, the etching process may include alternative etchants to separately remove various layers of dummy gate stacks 209, such as dummy gate electrode layers, dummy gate dielectric layers, and/or dummy hard mask layers. In some embodiments, the etching process is configured to selectively etch dummy gate stacks 209 with minimal (to no) etching of other features of the device 200, such as ILD layer 900, gate spacers 211, semiconductor layers 204a, and interposer layers 205. In some embodiments, a lithography process is performed to form a patterned mask layer that covers ILD layer 900 and/or gate spacers 211, and the etching process uses the patterned mask layer as an etch mask.

Second, as shown in FIGS. 21A-21C, the interposer layers 205 (exposed by the gate trenches 275) are selectively removed from the channel regions CR, forming suspended semiconductor channels 240. In other words, what remains of the semiconductor layers 204a now become suspended semiconductor channels 240. This removal process is also known as channel-release, and this stage of the manufacturing process is referred to as the channel-release stage. In the depicted embodiment, an etching process selectively etches interposer layers 205 with minimal (to no) etching of semiconductor layers 204a and, in some embodiments, minimal (to no) etching of gate spacers 211 and/or inner spacers 216. Various etching parameters can be tuned to achieve selective etching of semiconductor layers 204b, such as etchant composition, etching temperature, etching solution concentration, etching time, etching pressure, source power, RF bias voltage, RF bias power, etchant flow rate, other suitable etching parameters, or combinations thereof. For example, an etchant is selected for the etching process that etches the material of interposer layer 205 (in the depicted embodiment, silicon oxide) at a higher rate than the material of semiconductor layers 204a (in the depicted embodiment, silicon) (i.e., the etchant has a high etch selectivity with respect to the material of interposer layers 205). The etching process is a dry etching process, a wet etching process, other suitable etching process, or combinations thereof.

Notably, referring to FIG. 21C, due to the presence of the hard mask structure 207, the channel-release process to etch away the interposer layer 205 does not cause damage or loss to the isolation structure 206. For example, in the present embodiment, both the isolation structure 206 and the interposer layers 205 are made of silicon oxide. Without the hard mask structure 207, when the interposer layers 205 are etched away to form suspended semiconductor channels 240, the isolation structure 206 would also be etched resulting in damage. The hard mask structure 207 ensures the structural integrity of the isolation structure 206 so that it can provide proper isolation between fin active regions.

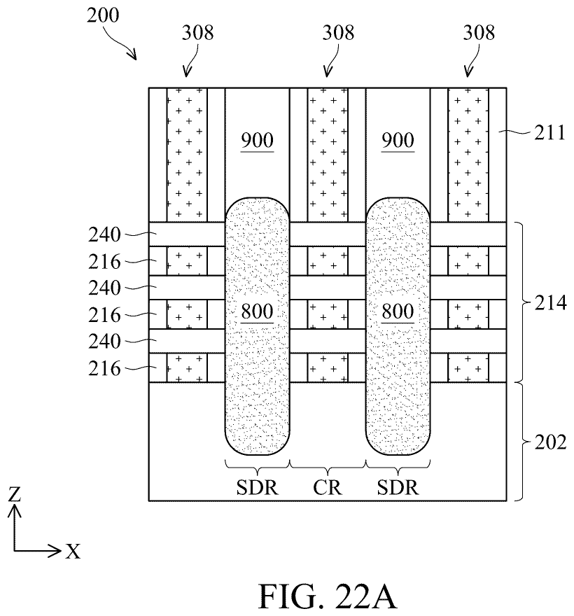

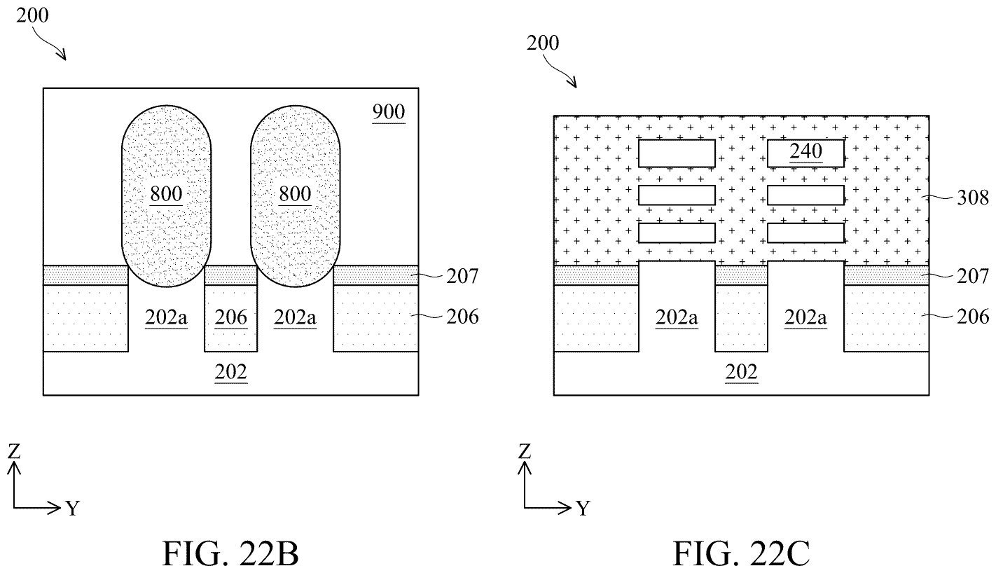

Referring now to FIGS. 22A-22C collectively, the method 1000 at operation 1016 forms metal gate structures 308 over the channel regions CR and wrapping around each of the suspended semiconductor channels 240. Although not shown, each of the metal gate structures 308 may include a gate dielectric layer and a gate electrode disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The gate electrodes may be formed by a CVD process or a PVD process that deposits a metal fill layer that fills remaining portions of the gate trenches 275 and over the gate dielectric layers. The metal fill layer includes a suitable conductive material, such as Al, W, and/or Cu. The metal fill layer may additionally or collectively include other metals, metal oxides, metal nitrides, other suitable materials, or combinations thereof. Alternatively, the metal fill layer is formed using another suitable deposition process, such as ALD, CVD, PVD, HDPCVD, MOCVD, RPCVD, PECVD, LPCVD, ALCVD, APCVD, spin coating, plating, other deposition process, or combinations thereof.

A planarization process is performed to remove excess gate materials from the semiconductor device 200. For example, a CMP process is performed until a top surface of the ILD layer 900 is reached (exposed) so that top surfaces of the metal gate structures 308 are substantially planar with a top surface of ILD layer 900 after the CMP process. Accordingly, the semiconductor device 200 now forms GAA transistors having metal gate structures 308 wrapping respective semiconductor channels 240 (now no longer suspended), where the metal gate structures 308 are disposed between respective semiconductor channels 240 along the z direction and between respective epitaxial S/D features 800 along the x direction. Further, the metal gate structures 308 are separated from the S/D features 800 by the gate spacers 211 and the inner spacers 216.

Referring to FIG. 22C, the metal gate structures 308 directly land on the hard mask structure 207, which has a top surface slightly below top surfaces of the protruding portions 202a of the substrate 202. A height difference between top surfaces of the protruding portions 202a and the top surface of the hard mask structure 207 should be small and may be defined by the height h1 minus the thickness t4 previously described. With the isolation structure 206 protected by the hard mask structure 207, this small height difference can be achieved such that the metal gate structures 308 are prevented from penetrating into the isolation structure 206, which may otherwise cause unwanted leakage and coupling between the metal gate structures 308 and the protruding portions 202a of the substrate 202.

The method 1000 may perform further steps to complete fabrication of the semiconductor device 200. For example, the method 1000 further forms S/D contacts over the S/D features 800, gate contacts over the metal gate structure 308, and interconnect structures having interconnect metal lines and vias over the S/D and gate contacts. Additional operations can be provided before, during, and after method 1000. Further, some of the operations described can be moved, replaced, or eliminated for additional embodiments of method 1000.

Although not limiting, the present disclosure offers advantages for semiconductor devices having an isolation structure. One example advantage is forming a hard mask layer over the isolation structure to protect the isolation structure from being damaged. Another example advantage is tuning the hard mask layer to have a planar profile.

One aspect of the present disclosure pertains to a method of forming a semiconductor device. The method includes forming a semiconductor stack with interleaved first and second semiconductor layers over a substrate; patterning the semiconductor stack and the substrate to form semiconductor fins having semiconductor stack portions over base portions; depositing an isolation layer over the semiconductor fins; recessing the isolation layer to form an isolation structure surrounding base portions of the semiconductor fins; depositing a hard mask layer over the semiconductor fins and over the isolation structure, the hard mask layer includes bottom portions disposed on the isolation structure, sidewall portions disposed on sidewalls of the semiconductor fins, and top portions disposed on top surfaces of the semiconductor fins; performing a first etching process to recess the top portions of the hard mask layer; and performing a second etching process to planarize the bottom portions of the hard mask layer, thereby forming a hard mask structure with a planarized top surface over the isolation structure.

In an embodiment, the first etching process includes a dry etching process, and the second etching process includes a wet etching process. In a further embodiment, the dry etching process includes anisotropic plasma etching using NH3 and H2 as plasma etching gases. In a further embodiment, the wet etching process includes isotropic wet etching using H3PO4 as an etching agent.

In an embodiment, the isolation structure includes an oxide-based dielectric and the hard mask layer includes a nitride-based dielectric.

In an embodiment, a top surface of the hard mask structure is below the semiconductor stack portions of the semiconductor fins.

In an embodiment, the first etching process further includes: depositing a sacrificial layer over the hard mask layer; and simultaneously dry etching top portions the sacrificial layer and the top portions of the hard mask layer. The top portions of the sacrificial layer is etched until at least top surfaces of the semiconductor fins is above a top surface of the sacrificial layer.

In a further embodiment, the sacrificial layer is deposited by spin-on coating, and the sacrificial layer is a bottom antireflective coating (BARC) layer having silicon-containing polymers, carbon-containing polymers, or spin-on carbon (SOC).

In an embodiment, the second etching process further includes: removing remaining portions of the sacrificial layer to expose the sidewall and the bottom portions of the hard mask layer; and wet etching the hard mask layer to simultaneously: remove the recessed top portions of the hard mask layer and the sidewall portions of the hard mask layer, and planarize the bottom portions of the hard mask layer.

In a further embodiment, the removing of the remaining portions of the sacrificial layer includes performing a plasma ashing or a wet stripping process.

Another aspect of the present disclosure pertains to a method of forming a semiconductor device. The method includes receiving a workpiece having semiconductor fins with interleaved first and second semiconductor layers, wherein the semiconductor fins are disposed over protruding portions of a base substrate; forming a shallow trench isolation (STI) structure over the base substrate and surrounding the protruding portions of the base substrate; forming a hard mask structure with a planarized top surface over the STI structure, the planarized top surface is below a top surface of the protruding portions of the base substrate, the hard mask structure is thinner than the STI structure, and the hard mask structure and the STI structure include different dielectric materials; forming dummy gates over channel regions of the semiconductor fins and over the hard mask structure; forming S/D trenches adjacent to the channel regions, thereby exposing side surfaces of the semiconductor fins; replacing the second semiconductor layers with interposer layers, wherein the interposer layers include a same dielectric material as the STI structure; epitaxially growing S/D features in the S/D trenches; forming an interlayer dielectric (ILD) layer over the S/D features; removing the dummy gates to expose the semiconductor fins; forming suspended semiconductor channels by selectively etching away the interposer layers while the hard mask structure protects the STI structure from being etched; and forming metal gate structures over the channel regions and wrapping around each of the suspended semiconductor channels.

In an embodiment, the forming of the hard mask structure includes: depositing a hard mask layer over the semiconductor fins and over the STI structure, the hard mask layer includes bottom portions disposed on the STI structure, sidewall portions disposed on sidewalls of the semiconductor fins, and top portions disposed on top surfaces of the semiconductor fins; performing a first etching process to recess top portions of the hard mask layer; and performing a second etching process to planarize the bottom portions of the hard mask layer, thereby forming the hard mask structure with the planarized top surface over the STI structure.

In a further embodiment, after performing the first etching process and before the performing of the second etching process, the bottom portions of the hard mask layer have a greater thickness than the top portions of the hard mask layer.

In a further embodiment, before the performing of the second etching process, the bottom portions of the hard mask layer have convex rounded surfaces.

In an embodiment, the STI structure includes silicon oxide and the hard mask structure includes silicon nitride, and a thickness ratio of the STI structure to the hard mask structure ranges between about 2 to about 30.

In an embodiment, the suspended semiconductor channels are made of pure silicon, and the protruding portions of the base substrate are made of silicon doped with boron or phosphorus.

Another aspect of the present disclosure pertains to a semiconductor device. The semiconductor device includes stacks of semiconductor channels disposed above protruding portions of a substrate; an isolation structure over the substrate and surrounding the protruding portions of the substrate; and a metal gate structure over the isolation structure and wrapping around each semiconductor channel in the stacks of semiconductor channels. The isolation structure includes a shallow trench isolation (STI) layer and a hard mask layer over the STI layer. The STI layer includes silicon oxide and the hard mask layer includes silicon nitride. The STI layer is thicker than the hard mask layer.

In an embodiment, each semiconductor channel in the stacks of semiconductor channels are made of pure silicon, and the protruding portions of the substrate are made of silicon doped with boron or phosphorus.

In an embodiment, the STI layer has a first thickness, the hard mask layer has a second thickness, and a ratio of the first thickness to the second thickness ranges between about 2 to about 30. In a further embodiment, each semiconductor channel in the stacks of semiconductor channels has a third thickness, and the second thickness has about the same thickness as the third thickness.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
forming a semiconductor stack with interleaved first and second semiconductor layers over a substrate;
patterning the semiconductor stack and the substrate to form semiconductor fins having semiconductor stack portions over base portions;
depositing an isolation layer over the semiconductor fins;
recessing the isolation layer to form an isolation structure surrounding base portions of the semiconductor fins;
depositing a hard mask layer over the semiconductor fins and over the isolation structure, the hard mask layer includes bottom portions disposed on the isolation structure, sidewall portions disposed on sidewalls of the semiconductor fins, and top portions disposed on top surfaces of the semiconductor fins;
performing a first etching process to recess the top portions of the hard mask layer; and
performing a second etching process to planarize the bottom portions of the hard mask layer, thereby forming a hard mask structure with a planarized top surface over the isolation structure.

2. The method of claim 1, wherein the first etching process includes a dry etching process, and the second etching process includes a wet etching process.

3. The method of claim 2, wherein the dry etching process includes anisotropic plasma etching using NH₃ and H₂ as plasma etching gases.

4. The method of claim 3, wherein the wet etching process includes isotropic wet etching using H₃PO₄ as an etching agent.

5. The method of claim 1, wherein the isolation structure includes an oxide-based dielectric and the hard mask layer includes a nitride-based dielectric.

6. The method of claim 1, wherein a top surface of the hard mask structure is below the semiconductor stack portions of the semiconductor fins.

7. The method of claim 1, wherein the first etching process further includes:
depositing a sacrificial layer over the hard mask layer; and
simultaneously dry etching top portions the sacrificial layer and the top portions of the hard mask layer,
wherein the top portions of the sacrificial layer is etched until at least top surfaces of the semiconductor fins is above a top surface of the sacrificial layer.

8. The method of claim 7, wherein the sacrificial layer is deposited by spin-on coating, and the sacrificial layer is a bottom antireflective coating (BARC) layer having silicon-containing polymers, carbon-containing polymers, or spin-on carbon (SOC).

9. The method of claim 7, wherein the second etching process further includes:
removing remaining portions of the sacrificial layer to expose the sidewall and the bottom portions of the hard mask layer; and
wet etching the hard mask layer to simultaneously:
remove the recessed top portions of the hard mask layer and the sidewall portions of the hard mask layer, and
planarize the bottom portions of the hard mask layer.

10. The method of claim 9, wherein the removing of the remaining portions of the sacrificial layer includes performing a plasma ashing or a wet stripping process.

11. A method of forming a semiconductor device, comprising:
receiving a workpiece having semiconductor fins with interleaved first and second semiconductor layers, wherein the semiconductor fins are disposed over protruding portions of a base substrate;
forming a shallow trench isolation (STI) structure over the base substrate and surrounding the protruding portions of the base substrate;
forming a hard mask structure with a planarized top surface over the STI structure, wherein the planarized top surface is below a top surface of the protruding portions of the base substrate, wherein the hard mask structure is thinner than the STI structure, and the hard mask structure and the STI structure include different dielectric materials;
forming dummy gates over channel regions of the semiconductor fins and over the hard mask structure;
forming S/D trenches adjacent to the channel regions, thereby exposing side surfaces of the semiconductor fins;
replacing the second semiconductor layers with interposer layers, wherein the interposer layers include a same dielectric material as the STI structure;
epitaxially growing S/D features in the S/D trenches;
forming an interlayer dielectric (ILD) layer over the S/D features;
removing the dummy gates to expose the semiconductor fins;
forming suspended semiconductor channels by selectively etching away the interposer layers while the hard mask structure protects the STI structure from being etched; and
forming metal gate structures over the channel regions and wrapping around each of the suspended semiconductor channels.

12. The method of claim 11, wherein the forming of the hard mask structure includes:
depositing a hard mask layer over the semiconductor fins and over the STI structure, the hard mask layer includes bottom portions disposed on the STI structure, sidewall portions disposed on sidewalls of the semiconductor fins, and top portions disposed on top surfaces of the semiconductor fins;
performing a first etching process to recess top portions of the hard mask layer; and
performing a second etching process to planarize the bottom portions of the hard mask layer, thereby forming the hard mask structure with the planarized top surface over the STI structure.

13. The method of claim 12, wherein after performing the first etching process and before the performing of the second etching process, the bottom portions of the hard mask layer have a greater thickness than the top portions of the hard mask layer.

14. The method of claim 12, wherein before the performing of the second etching process, the bottom portions of the hard mask layer have convex rounded surfaces.

15. The method of claim 11, wherein the STI structure includes silicon oxide and the hard mask structure includes silicon nitride, and a thickness ratio of the STI structure to the hard mask structure ranges between about 2 to about 30.

16. The method of claim 11, wherein the suspended semiconductor channels are made of pure silicon, and the protruding portions of the base substrate are made of silicon doped with boron or phosphorus.

17. A semiconductor device, comprising:
stacks of semiconductor channels disposed above protruding portions of a substrate;
an isolation structure over the substrate and surrounding the protruding portions of the substrate; and
a metal gate structure over the isolation structure and wrapping around each semiconductor channel in the stacks of semiconductor channels,
wherein the isolation structure includes a shallow trench isolation (STI) layer and a hard mask layer over the STI layer, wherein the STI layer includes silicon oxide and the hard mask layer includes silicon nitride,
wherein the STI layer is thicker than the hard mask layer.

18. The semiconductor device of claim 17, wherein each semiconductor channel in the stacks of semiconductor channels are made of pure silicon, and the protruding portions of the substrate are made of silicon doped with boron or phosphorus.

19. The semiconductor device of claim 18, wherein the STI layer has a first thickness, the hard mask layer has a second thickness, and a ratio of the first thickness to the second thickness ranges between about 2 to about 30.

20. The semiconductor device of claim 19, wherein each semiconductor channel in the stacks of semiconductor channels has a third thickness, and the second thickness has about the same thickness as the third thickness.
